(19) United States
(12) Patent Application Publication
(10) Pub. No.: US 2023/0422432 A1
(43) Pub. Date: Dec. 28, 2023

(54) SELF-SERVICE TERMINAL WITH TEMPERATURE ADJUSTMENT ASSEMBLY AND METHOD FOR ITS OPERATION

(71) Applicant: ELO TOUCH SOLUTIONS, INC., Knoxville, TN (US)

(72) Inventors: Yin SUN, Shanghai (CN); Xueqing WEI, Shanghai (CN); Jinfeng ZHANG, Shanghai (CN)

(73) Assignee: ELO TOUCH SOLUTIONS, INC., Knoxville, TN (US)

(21) Appl. No.: 18/212,497

(22) Filed: Jun. 21, 2023

(30) Foreign Application Priority Data
Jun. 22, 2022 (CN) 202210710826.1

(51) Int. Cl. H05K 7/20; G07G 1/00

(52) U.S. Cl. CPC H05K 7/20209; H05K 7/20145; G07G 1/0018

(57) ABSTRACT

The present disclosure relates to a self-service terminal, comprising: a first cavity configured as a first accommodating space of the self-service terminal; a second cavity configured as a second accommodating space of the self-service terminal; a temperature adjustment assembly disposed between the first cavity and the second cavity, the temperature adjustment assembly is configured to adjust the temperature within the first cavity and/or the second cavity, and the temperature adjustment assembly is configured to physically partition the first cavity and the second cavity. Thereby, a self-service terminal that can operate stably and reliably may be provided. Furthermore, the present disclosure also relates to a method for operating the self-service terminal.

### CROSS-REFERENCE TO RELATED APPLICATIONS

The present application claims the benefit and priority of Chinese Application No. 202210710826.1, filed Jun. 22, 2022 entitled “Self-service terminal with temperature adjustment assembly and method for its operation,” the entire contents of which is incorporated herein by reference in its entirety for all purposes.

### BACKGROUND OF THE INVENTION

### Technical Field

The present disclosure generally relates to the technical field of self-service, more particularly, to a self-service terminal with temperature adjustment assembly and a method for its operation.

### Background Art

At present, as the popularization of the Internet and the promotion of electronic payment methods, in the industries such as retail, catering etc., many self-service terminals that basically do not require the assistance of staff and may be operated by customers themselves have been developed, e.g., the self-service terminal where customers order food. These self-service terminals reduce labor costs while providing convenience and saving time for customers.

The self-service terminals may be placed at a variety of locations. In some cases, the self-service terminals may be placed indoors (e.g., in stores etc.). In some cases, the self-service terminals may be placed outdoors (e.g., outside stores, by roads, at stations, etc.). No matter the self-service terminals are placed indoors or outdoors, a stable and reliable operation of the self-service terminals is desired. Especially when the self-service terminal is placed outdoors, the self-service terminal may be exposed to more extreme weather conditions, such as rain, high temperature, cold, freezing, and the like.

### SUMMARY OF THE INVENTION

Therefore, an object of the present disclosure is to provide a self-service terminal capable of stable and reliable operation and a method for operating the self-service terminal.

According to a first aspect of the present disclosure, a self-service terminal is provided, comprising: a first cavity configured as a first accommodating space of the self-service terminal; a second cavity configured as a second accommodating space of the self-service terminal; a temperature adjustment assembly disposed between the first cavity and the second cavity, the temperature adjustment assembly is configured to adjust the temperature within the first cavity and/or the second cavity, and the temperature adjustment assembly is configured to physically partition the first cavity and the second cavity.

According to a second aspect of the present disclosure, a self-service terminal is provided, comprising: a first cavity configured as an upper layer space of the self-service terminal, and a terminal control module is provided in the upper layer space; a second cavity configured as a lower layer space of the self-service terminal, a temperature control board is provided in the lower layer space; a temperature adjustment assembly as an intermediate layer arranged between the first cavity and the second cavity, the temperature control board is configured to control the operation of the temperature adjustment assembly such that the temperature adjustment assembly adjusts the temperature in the first cavity so that the temperature in the first cavity is within a predetermined temperature range.

According to a third aspect of the present disclosure, a method for a self-service terminal is provided, the method comprising: acquiring a first temperature measurement value of a first temperature sensor located in a first cavity; and comparing the first temperature measurement value with a first upper temperature threshold and/or a first lower temperature threshold; when the first temperature measurement value is higher than the first upper temperature threshold, a first control command for the temperature adjustment assembly is generated to cause the temperature adjustment assembly to conduct a cooling treatment for the first cavity, and/or when the first temperature measurement value is lower than the first lower temperature threshold, a second control command for the temperature adjustment assembly is generated to cause the temperature adjustment assembly to conduct a heating treatment for the first cavity.

### DESCRIPTION OF THE DRAWINGS

The present disclosure is explained in more detail below with reference to the accompanying drawings by means of specific embodiments. A brief description of the schematic drawings is as follows:

FIG. 1 is a perspective view of a self-service terminal according to some embodiments of the present disclosure, wherein a portion of the covering on the rear side of the self-service terminal is removed to expose a first cavity.

FIG. 2 is a first rear view of the self-service terminal of FIG. 1.

FIG. 3 is a second rear view of the self-service terminal of FIG. 1.

FIG. 4 is a side view of the self-service terminal of FIG. 1.

FIG. 5 is a partial perspective view of the self-service terminal according to some embodiments of the present disclosure.

FIG. 6 is a perspective view of the temperature adjustment assembly of FIG. 5.

FIG. 7 is a simplified schematic block diagram of a self-service terminal according to some embodiments of the present disclosure.

FIG. 8 is an exemplary block diagram of the temperature control board of FIG. 7.

FIG. 9 is an exemplary flowchart of a method for operating a self-service terminal according to some embodiments of the present disclosure.

Note that, in the embodiments described below, sometimes the same reference number is used to denote the same part or parts having the same function in the different Figures, and repeated descriptions thereof may be omitted. In some instances, similar numerals and letters are used to denote similar items, so once an item is defined in one figure, it does not require further discussion in subsequent figures.

### DETAILED EMBODIMENTS

The present disclosure will be described below with reference to the accompanying drawings, which illustrate several examples of the disclosure. It should be understood, however, that this disclosure may be presented in many different forms and is not limited to the examples described below. In fact, the examples described below intend to make the present disclosure complete, and to fully explain the protection scope of the present disclosure to those skilled in the art. It should also be understood that the examples disclosed herein may be combined in various ways to provide still further examples.

It is understood that the phraseology herein is used to describe particular examples only and is not intended to limit the scope of the present disclosure. All terms (including technical terms and scientific terms) used herein have the meanings commonly understood by those skilled in the art unless otherwise defined. Well-known functions or constructions may not be described in detail for brevity and/or clarity.

In the context, spatially relative terms such as “up”, “down”, “left”, “right”, “front”, “rear”, “high”, “low” etc. can illustrate the relationship of one feature and another feature in the attached figure. It is to be understood that spatially relative terms encompass different orientations of the device in use or operation in addition to the orientation shown in the figures. For example, when the device in the figures is turned over, features previously described as “below” other features may now be described as “above” the other features. The device may also be otherwise oriented (rotated 90 degrees or at other orientations) in which case the relative spatial relationships will be interpreted accordingly.

As used herein, the term “A or B” includes “A and B” and “A or B”, but not exclusively only comprise “A” or only comprise “B” unless specifically stated otherwise.

As used herein, the term “schematic” or “exemplary” means “serving as an example, instance, or illustration” rather than as a “model” to be exactly reproduced. Any implementation illustratively described herein is not necessarily to be construed as preferred or advantageous over other implementations. Furthermore, the present disclosure is not to be bound by any expressed or implied theory presented in the preceding technical field, background, brief summary or detailed description.

As used herein, the term “substantially” intends to encompass any minor variation due to design or manufacturing imperfections, tolerances of devices or elements, environmental influences, and/or other factors.

Also, terms like “first”, “second” and the like may also be used herein for reference purposes only, and are thus not intended to be limiting. For example, the terms “first”, “second” and other such numerical terms referring to structures or elements do not imply a sequence or order unless the context clearly dictates.

The present disclosure relates to a self-service terminal which is suitable not only for indoor operation but also for outdoor operation. The outdoor environment herein refers to the environment without covering to protect the self-service terminal, including but not limited to outside the buildings such as houses, beside roads, at the stations, and other open-air environments without coverings. The self-service terminal placed outdoors may be exposed to more extreme weather conditions, such as rain, high temperature, cold, freezing, and the like. These extreme weather conditions place higher demands on the temperature regulation and/or water and dust resistance of the self-service terminal. The self-service terminal of the present disclosure can maintain stable and reliable operation in an “outdoor” environment.

It should be understood that the self-service terminals of the present disclosure may be used for various purposes (e.g., self-ordering, self-checkout, printing tickets by self-service, self-registration, self-consultation, etc.) in various industries (e.g., retail, restaurant, hospitality, medical, entertainment, or transportation industries). Of course, the application of the self-service terminal is not limited thereto, but may be used in various self-service occasions that do not require staff to operate, and the equipped functional components can also be changed according to the application occasions.

Some embodiments of the present disclosure will now be described in more detail with reference to the accompanying drawings.

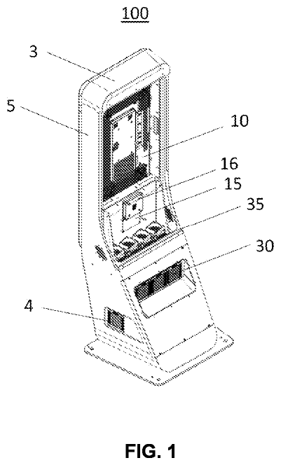

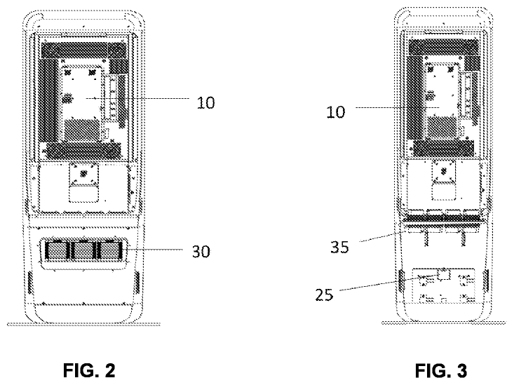

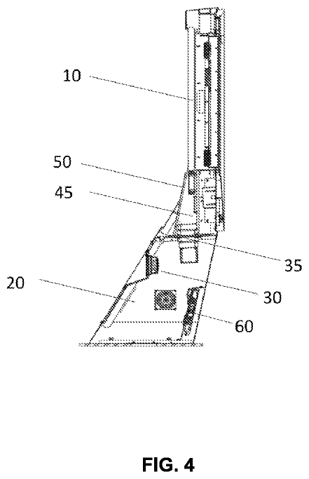

FIG. 1 is a partial perspective view of the self-service terminal 100 according to some embodiments of the present disclosure. FIGS. 2 and 3 are rear views of the self-service terminal 100 of FIG. 1, respectively. FIG. 4 is a side view of the self-service terminal 100 of FIG. 1.

As shown in FIG. 1, the self-service terminal 100 may include an outer casing 5 (e.g., a metal casing) and a cavity formed in the outer casing 5 as an accommodating space, and various functional components may be installed in the corresponding cavity, such as display screen, control boards, scanners, power supplies, sensors, and so on.

The self-service terminal 100 may include a first cavity 10 and a second cavity 20 separated from the first cavity 10 (see FIG. 3). In the current example, the first cavity 10 may be configured as an upper layer space of the self-service terminal 100, and the second cavity 20 may be configured as a lower layer space of the self-service terminal 100. In FIG. 1, a cover (e.g., a plastic cover) is removed, thereby exposing the first cavity 10 of the self-service terminal 100. It should be understood that in normal operation of the self-service terminal 100, the corresponding cover will close the first cavity 10 on the rear side.

It should be understood that the first cavity 10 and the second cavity 20 may also have other possible arrangements. In some embodiments, the first cavity 10 may be configured as a lower layer space of the self-service terminal 100, and the second cavity 20 may be configured as an upper layer space of the self-service terminal 100. In other example, the first cavity 10 may be configured as a left space of the self-service terminal 100, and the second cavity 20 may be configured as a right space of the self-service terminal 100.

In order to meet the outdoor operation requirements of the self-service terminal 100, good waterproof and dustproof performance and thermal insulation performance of the corresponding cavity should be ensured to avoid being affected by extreme weather conditions, such as rain, high temperature, cold, freezing, etc. For the purpose of waterproofing, the top 3 of the self-service terminal 100 may be constructed with a stepped waterproof structure and a water guide groove on the side, so as to effectively prevent rainwater from penetrating into the cavity.

In addition, a thermal insulation layer (e.g., thermal insulation cotton) and/or a radiation reflective film (e.g., metal foil) may be provided on the inner surface of the outer casing 5 of the self-service terminal 100 facing the cavity (e.g., the first cavity 10). Thus, in the operation state of the self-service terminal 100, the corresponding cavity (e.g., the first cavity 10) forms a substantially closed heat-insulating cavity.

The present disclosure divides the self-service terminal 100 into at least two cavities. Different cavities may have different levels of water and dust resistance and/or different levels of thermal insulation. For this purpose, each cavity may be arranged with different functional components. Typically, different functional components have their own set operating conditions, such as set operating temperature ranges. Once the temperature goes beyond the set operating temperature range, the corresponding functional components may not perform their functions well or even malfunction. To this end, it is desirable that the corresponding cavity can satisfy the set operating conditions of the corresponding functional components.

In the current examples, in the operation state of the self-service terminal 100, the first cavity 10 may be constructed as a substantially closed thermally insulated cavity. That is to say, the first cavity 10 may have high waterproof and dustproof performance and thermal insulation performance, so as to allow the installation of critical functional components for the operation of the self-service terminal 100 in the first cavity 10, such as a terminal control module 15 (TCM) and/or a computer module 16 (also known as android box). In some embodiments, the terminal control module 15 may be constructed as or include a printed circuit board, on which a control unit, a communication unit, a storage unit, and the like may be integrated. Generally, the terminal control module 15 and/or the computer module 16 has/have high requirements on the operating temperature. Once the operating temperature goes beyond the set operating temperature range (e.g., 0 to 40 degrees), its performance will be affected, thereby affecting the operation of the self-service terminal 100.

In some embodiments, the self-service terminal 100 may be divided into a three-layer system architecture comprising application layer devices, middle layer devices, and bottom layer devices. By dividing the system of the self-service terminal 100 into a three-layer architecture and using the terminal control module 15 of the middle layer to centrally control the bottom-layer peripheral devices, the application layer device only needs to match and communicate with the terminal control module 15 of the middle layer, so as to control all peripherals without knowing their specific configuration. Therefore, the application layer device can easily control the entire self-service terminal 100. In addition, the self-service terminal 100 can easily change/upgrade the bottom-layer peripherals without changing the more complex programs run by the application-layer equipment, thereby making the operation and maintenance and hardware upgrade of the entire self-service terminal 100 more convenient.

In some embodiments, terminal control module 15 may control the operation of other functional components within self-service terminal 100, such as computer modules, touch screens, scanners, printing devices, microphones, cameras, degaussing devices, and the like. In some embodiments, the terminal control module 15 may undertake the power supply function for some functional components. In some embodiments, the terminal control module 15 may have a temperature measurement function.

In some embodiments, in the operation state of the self-service terminal 100, the second cavity 20 may be configured to have higher waterproof and dustproof performance and thermal insulation performance, thereby allowing the installation of critical functional components for the operation of the self-service terminal 100 in the second cavity 20, such as the temperature control board 25, the power supply 60, and the like. In some embodiments, a cooling fan 30 and an air inlet 4 conforming to a specific waterproof and dustproof standard may be installed in the second cavity 20, and the second cavity 20 may be configured to be in a negative pressure state to achieve an improved heat dissipation effect.

Nevertheless, stable and reliable operation of the self-service terminal 100 cannot be guaranteed under some extreme weather conditions. For example, in the case of high temperature (such as outdoor temperature higher than 40 degrees or even 50 degrees) or low temperature (such as outdoor temperature below minus 10 degrees, 20 degrees or even 30 degrees), some functional components may not work properly.

In order to allow stable and reliable operation of the self-service terminal 100 in some extreme weather conditions, the self-service terminal 100 of the present disclosure is provided with temperature regulation capabilities.

As shown in FIGS. 1 to 4, the self-service terminal 100 may further include a temperature adjustment assembly 35. The temperature adjustment assembly 35 may be configured to adjust the temperature within the first cavity 10 and/or the second cavity 20. As an example, when the temperature in the first cavity 10 is higher than a predetermined temperature threshold due to high temperature outdoor weather, the temperature adjustment assembly 35 may execute a temperature regulation strategy according to a preset program and may be configured to reduce the temperature in the first cavity 10 by that the temperature adjustment assembly 35 may be configured in a cooling mode and to deliver cooling air to the first cavity 10 such that the first cavity 10 is in a “refrigerator mode”. As an example, when the temperature in the first cavity 10 is lower than a predetermined temperature threshold due to low temperature outdoor weather, the temperature adjustment assembly 35 may execute a temperature regulation strategy according to a preset program and may be configured to increase the temperature in the first cavity 10 by that the temperature adjustment assembly 35 may be configured in a warming mode and to deliver heating air to the first cavity 10 such that the first cavity 10 is in a “warmer mode”.

In the current example, the temperature adjustment assembly 35 is arranged between the first cavity 10 and the second cavity 20 as an intermediate layer. The temperature adjustment assembly 35 may be configured to physically separate the first cavity 10 and the second cavity 20, such that the first cavity 10 and the second cavity 20 are sealed from each other.

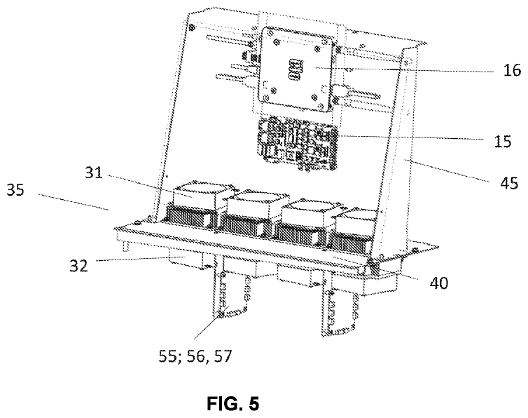

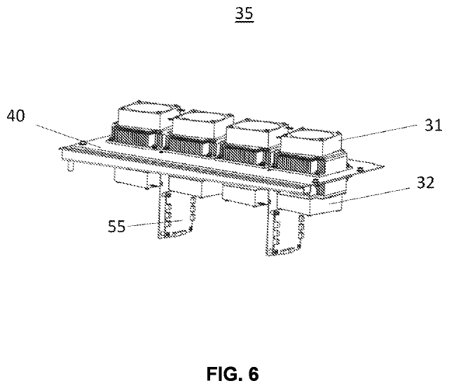

Referring to FIGS. 5 and 6, the temperature adjustment assembly 35 of the self-service terminal 100 according to some embodiments of the present disclosure is introduced.

The temperature regulation assembly 35 may include a semiconductor temperature regulator 40 or a thermoelectric temperature regulator (TEC, also sometimes referred to as a cooling plate). The semiconductor temperature regulator 40 is made by using the Peltier effect of semiconductor materials. When there is current flowing through the TEC, the heat generated by the current is transferred from the first temperature regulating surface of the TEC to the opposite second temperature regulating surface, creating a “hot side” and a “cold side” on the TEC, thereby producing the TEC's heating and cooling effects.

The temperature adjustment assembly 35 may also include a first fan 31 and/or a first heat sink installed at the first temperature regulating surface of the semiconductor temperature regulator 40 and a second fan 32 and/or a second heat sink installed at the second temperature regulating surface of the semiconductor temperature regulator 40. In some embodiments, the respective fans 31, 32 may be configured to direct the cooling airflow or the heating airflow toward the respective cavity, accelerating the heating and cooling effects. In some embodiments, fans 31, 32 and heat sinks on the “hot side” of the TEC may be configured to reduce the temperature of the TEC itself, avoiding damage to the TEC.

As shown in FIG. 5, the first temperature regulating surface of the semiconductor temperature regulator 40 and the fan 31 installed at the first temperature regulating surface may be arranged toward the first cavity 10 for directing the cooling airflow or the heating airflow toward the first cavity 10. To ensure that critical functional components, as well as temperature sensitive functional components, can function properly in some extreme weather conditions, it may be advantageous to locate these functional components close to the temperature regulation assembly 35. Advantageously, air guides 50 (see FIG. 4) may be added so that cooling airflow or heating airflow may be directed towards the critical functional components as well as temperature sensitive functional components.

In the current example, the terminal control module 15 and the computer module 16 may be installed in a lower region of the first cavity 10 close to the temperature adjustment assembly 35. As shown in FIG. 5, the terminal control module 15 and the computer module 16 may be installed in an accommodating mechanism 45. The accommodating mechanism 45 may be configured in the shape of a dustpan. The accommodating mechanism 45 may include a base plate on the frontside and a side wall bent rearward from the base plate. The accommodating mechanism 45 may be mounted on the temperature adjustment assembly 35 (e.g. the first temperature regulating surface), e.g. by means of side walls. The base plate and the side walls of the accommodating mechanism 45 may define an accommodating space, the lower side of the accommodating space may accommodate the first temperature regulating surface and the fan 31 of the temperature adjustment assembly 35, and the upper side of the accommodating space may accommodate the terminal control module 15 and/or the computer module 16. Therefore, during temperature regulating, the fan 31 may direct the cooling airflow or the heating airflow toward the terminal control module 15 and/or the computer module 16 in the accommodating mechanism 45, thereby improving the temperature regulating efficiency and effect to the terminal control module 15 and/or the computer module 16.

It should be understood that the shape of the accommodating mechanism 45 may have various possibilities of modification and should not be limited to the current example. In some embodiments, corresponding air guides 50 (see FIG. 4), such as air guide plates, may be provided on the rear side of the accommodating mechanism 45. The air guide 50 may be constructed as an integral or removable covering for the accommodating mechanism 45. The air guide 50 may be configured, for example, to steadily direct the heated or cooled airflow from the fan 31 to the terminal control module 15 and/or the computer module 16. The arrangement of the air guide 50 is advantageous, which can guide the air flow to reach a predetermined height stably, while avoiding the deterioration of the temperature regulation effect caused by the premature sinking of the cool air or the disturbance of the air flow. In some embodiments, the accommodating mechanism 45 may have a constriction part so that the airflow velocity may be accelerated.

In addition, it should be understood that other functional components, such as a scanner 46, a printing device, and the like, may also be accommodated in the accommodation mechanism 45.

With continued reference to FIGS. 5 and 6, the temperature regulation assembly 35 also has a control means 55, such as a control circuit board, for controlling the operating mode of the semiconductor temperature regulator 40. The control means 55 may have a first control port 56 and a second control port 57 and control the operating mode of the semiconductor temperature regulator 40 based on the voltage levels applied to the first control port 56 and the second control port 57.

In some embodiments, when a high voltage level VCC is applied to the first control port 56 and a low voltage level GND is applied to the second control port 57, the semiconductor temperature regulator 40 is set in the first operating mode, i.e., the first temperature regulating surface of the semiconductor temperature regulator 40 is in the cooling mode, while the second temperature regulating surface of the semiconductor temperature regulator 40 is in the heating mode.

In some embodiments, when a low voltage level GND is applied to the first control port 56 and a high voltage level VCC is applied to the second control port 57, the semiconductor temperature regulator 40 is set in the second operating mode, i.e., the first temperature regulating surface of the semiconductor temperature regulator 40 is in the heating mode, while the second temperature regulating surface of the semiconductor temperature regulator 40 is in the cooling mode.

In some embodiments, when a low voltage level is applied to the first control port 56 and a low voltage level is applied to the second control port 57, the semiconductor temperature regulator 40 is set in a sleep mode with no temperature regulation. It is also possible that, when a high voltage level is applied to the first control port 56 and a high voltage level is applied to the second control port 57, the semiconductor temperature regulator 40 can also be placed in a sleep mode with no temperature regulation.

As shown in FIG. 5, in the current example, the corresponding control means 55 may be provided at the second temperature regulating surface of the temperature adjustment assembly 35. Corresponding control means 55 may extend from the second temperature regulating surface into the second cavity 20. The temperature control assembly 35 may have a plurality (here two) of semiconductor temperature regulators 40 and an associated plurality (here two) of control means 55.

The self-service terminal 100 of the present disclosure also has a temperature control board 25 (see FIG. 3) that is configured to control the operation of the temperature adjustment assembly 35. That is, the temperature control board 25 may be configured to control the operating mode (the first operating mode, the second operating mode or the sleep mode) of the temperature adjustment assembly 35 based on the current temperature value within the first cavity 10 and/or the second cavity 20.

As shown in FIG. 3, the temperature control board 25 may be installed in the second cavity 20. Advantageously, the temperature control board 25 may be installed below the second cavity 20 away from the temperature adjustment assembly 35 (as shown in FIG. 3) to avoid interference by the temperature adjustment assembly 35, because when the second temperature regulating surface is heating or cooling, the temperature adjustment assembly 35 may affect the operation of the temperature control board 25.

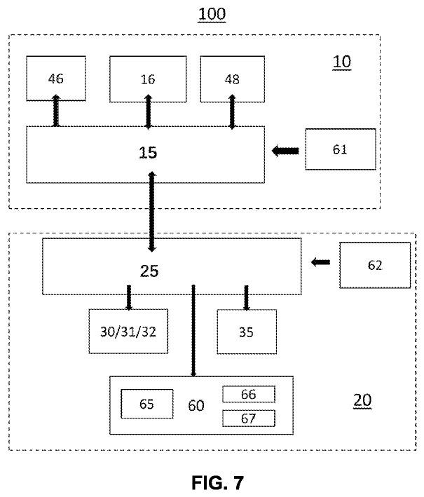

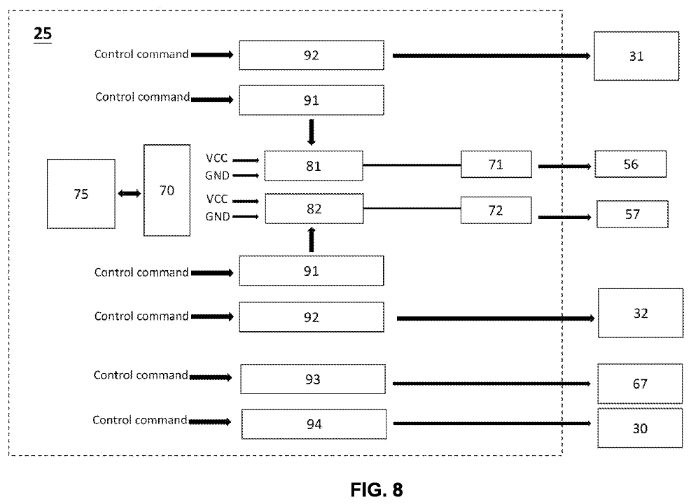

Next, the self-service terminal 100 and the temperature control board 25 within the self-service terminal 100 according to some embodiments of the present disclosure are further described with reference to FIGS. 7 and 8.

As shown in FIG. 7, the first cavity 10 is represented by a first dashed box, and the terminal control module 15 and some exemplary functional components, such as a scanner 46, a computer module 16 and a display 48, are provided in the first cavity 10. The terminal control module 15 may be configured to communicate with these functional components and to control the operation of these functional components, for example to supply power to these functional components. In addition, one or more temperature sensors 61 are provided in the first cavity 10, which are configured to detect the temperature in the first cavity 10 and communicate with the terminal control module 15 to transmit the detected temperature to the terminal control module 15. In some embodiments, one or more temperature sensors are disposed adjacent to the terminal control module 15 or directly mounted on the printed circuit board of the terminal control module 15 in order to more accurately obtain the operating temperature representing the terminal control module 15.

The second cavity 20 is represented by a second dashed box, and the temperature control board 25 and some exemplary functional components, such as the control means 55 for the temperature adjustment assembly 35, the fans 30, 31, 32, the power supply 60, etc. are provided in the second cavity 20. One or more temperature sensors 62 are provided in the second cavity 20, which are configured to detect the temperature in the second cavity 20 and communicate with the terminal control module 15 to transmit the detected temperature to the terminal control module 15. In addition, the temperature control board 25 may be connected in communication with the terminal control module 15. The temperature control board 25 may acquire the temperature parameters in the first cavity 10 from the terminal control module 15, and may receive control commands from the terminal control module 15. The temperature control board 25 may control the operation of some functional components (e.g., control means 55, fans 30, 31, 32, power supply 60) based on the control commands from the terminal control module 15, temperature parameters in the first cavity 10 and/or temperature parameters in the second cavity 20.

In some embodiments, one or more temperature sensors 62 are disposed adjacent to the temperature control board 25 or directly mounted on the temperature control board 25 in order to more accurately obtain the operating temperature representing the temperature control board 25. In some embodiments, since the higher requirements on the operating temperature of the power supply 60, one or more temperature sensors 62 are disposed adjacent to the power supply 60 in order to more accurately obtain the operating temperature representing the power supply 60.

In some embodiments, a dual power supply configuration is provided for the self-service terminal 100 to allow the self-service terminal 100 to operate reliably over a wide temperature range. A primary power supply 65, a secondary power supply 66, and a temperature regulating device 67 assigned to the secondary power supply 66 may be provided in the second cavity 20. In some embodiments, the temperature regulating device 67 may be designed as an electrical heating means. In some embodiments, the temperature regulating device 67 may be configured as a semiconductor temperature regulating device.

The primary power supply 65 has a first upper operating temperature threshold and/or a first lower operating temperature threshold, and the secondary power supply 66 has a second upper operating temperature threshold and/or a second lower operating temperature threshold, wherein the first upper operating temperature threshold is higher than the second upper operating temperature threshold, and/or the first lower operating temperature threshold is lower than the second lower operating temperature threshold. That is, the primary power supply 65 may have a higher or lower operating temperature, and thus may have a wider operating temperature range.

Under the normal operation, the secondary power supply 66 may operate normally to supply the power to the self-service terminal 100. However, in some extreme weather conditions, such as temperatures of minus 30 degrees or plus 50 degrees, the secondary power supply 66 may not function properly. In order to prevent the secondary power supply 66 from affecting the power supply to the self-service terminal 100, it may be provided that in the startup phase of the self-service terminal 100, the primary power supply 65 is responsible for the power supply of functional components related to temperature regulation, such as the terminal control module 15, the temperature control board 25 and the temperature adjustment assembly 35, fans 30, 31, 32, temperature regulating device 67 for the secondary power supply 66, etc. The temperature control board 25 may determine whether to activate the secondary power supply 66 and the temperature regulating device 67 for the secondary power supply 66 based on the temperature in the second cavity 20. When the temperature in the second cavity 20 is within the operating temperature range of the secondary power supply 66, the secondary power supply 66 powers on, and when the temperature in the second cavity 20 is outside the operating temperature range of the secondary power supply 66, the temperature control board 25 is configured to control the operation of the temperature regulating device 67 for the secondary power supply 66, so as to regulate the temperature of the secondary power supply 66 until it is within the operating temperature range, and then the secondary power supply 66 powers on. In some embodiments, the temperature control board 25 is configured such that when the temperature in the second cavity 20 is lower than the second lower operating temperature threshold and higher than the first lower operating temperature threshold, the temperature regulating device 67 functioned as a heater, and/or when the temperature in the second cavity 20 is higher than the second upper operating temperature threshold and lower than the first upper operating temperature threshold, the temperature regulating device 67 functioned as a cooler. Thus, the dual power supply configuration in this embodiment not only allows the self-service terminal 100 to better adapt to the outdoor operating environment, but also makes the cost of the self-service terminal 100 significantly reduced, because generally, the price of a power supply operating at a wide temperature range at the same power is much higher than that of a power supply operating at a narrow temperature range.

It should be understood that, in a single power supply configuration, a corresponding temperature regulating device 67 may also be configured for the power supply 60, so that the power supply 60 can continue to operate normally. In other examples, in the dual power supply configuration, corresponding temperature regulating devices may also be configured for the two power supplies, so that the two power supplies can continue to operate normally.

FIG. 8 exemplarily shows the temperature control board 25 within the self-service terminal 100.

As shown in FIG. 8, the temperature control board 25 may include a control unit 70, which may be configured to receive a first temperature measurement value of a first temperature sensor 61 located in the first cavity 10 and/or a second temperature measurement value of a second temperature sensor 62 located in the second cavity 20, and to output a control command based on the first temperature measurement value and/or the second temperature measurement value.

Additionally or alternatively, the control unit 70 may be configured to receive communication data from the terminal control module 15 based on the communication port 75 and output control commands based on the communication data.

The temperature control board 25 may include: a first output 71 configured to be connected (directly connected or indirectly connected) to the first control port 56 of the semiconductor temperature regulator 40; a first relay 81 configured to selectively provide a first high voltage level or a first low voltage level to the first output 71 and further to the first control port 56 of the semiconductor temperature regulator 40; a second output 72 configured to be connected (directly connected or indirectly connected) to the second control port 57 of the semiconductor temperature regulator 40; a second relay 82 configured to selectively provide a second high voltage level or a second low voltage level to the second output 72 and further to the second control port 57 of the semiconductor temperature regulator 40. In the current embodiment, high and low voltage levels are provided separately for each control port of the semiconductor temperature regulator 40 respectively, and a relay is used to selectively provide the corresponding high and low voltage levels, so that it can efficiently and reliably realize the control of the temperature control board 25 to temperature adjustment assembly 35, further to realize the efficient and reliable temperature regulating function of the self-service terminal 100.

The temperature control board 25 may include: a first driving circuit module 91 configured to drive the operating states of the first relay 81 and the second relay 82 based on the control command received from the control unit 70, so that the first high voltage level or the first low voltage level is supplied to the first output 71 via the first relay 81, and the second high voltage level or the second low voltage level is supplied to the second output 72 via the second relay 82. when the first high voltage level is provided to the first output 71 and the second low voltage level is provided to the second output 72, the first temperature regulating surface of the semiconductor temperature regulator 40 functions as a cooling surface and the second temperature regulating surface of the semiconductor temperature regulator 40 functions as a heating surface, and when the first low voltage level is provided to the first output 71 and the second high voltage level is provided to the second output 72, the first temperature regulating surface of the semiconductor temperature regulator 40 functions as a heating surface and the second temperature regulating surface of the semiconductor temperature regulator 40 functions as a cooling surface.

As shown in FIG. 8, the temperature control board 25 may include a second drive circuit module 92 configured to drive the operation of the fans 31 and 32 of the temperature adjustment assembly 35 based on the control commands received from the control unit 70, so that the fans 31, 32 are activated earlier than the semiconductor temperature regulator 40 by a predetermined period of time, and the fans 31, 32 are deactivated later than the semiconductor temperature regulator 40 by a predetermined period of time. This ensures that the temperature adjustment assembly 35 is not damaged by continuous heat generation.

Additionally or alternatively, the temperature control board 25 may include a third drive circuit module 93 configured to control the operation of the temperature regulating device 67 for the power supply (e.g., a secondary power supply in a dual power supply configuration) based on control commands received from the control unit 70, such that when the second temperature measurement value is below the lower operating temperature threshold of the power supply, the temperature regulating device 67 functions as a heater, and/or when the second temperature measurement value is higher than the upper operating temperature threshold of the power supply, the temperature regulating device 67 functions as a cooler.

Additionally or alternatively, the temperature control board 25 may include a fourth drive circuit module 94, which is configured to activate the fan 30 after the self-service terminal 100 powers on. Since the number of exhaust ports for the fan 30 is more than that of the air inlets 4, the second cavity 20 may be configured to be in a negative pressure state to achieve better heat dissipation.

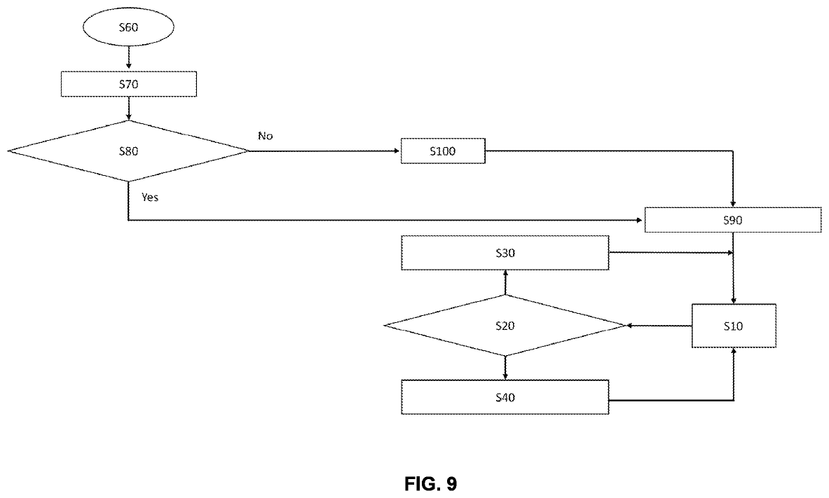

FIG. 9 is an exemplary flowchart of a method for the self-service terminal 100 according to some embodiments of the present disclosure. It should be pointed out that: the order of the steps of each method in this document may be flexibly configured, and the steps are marked with numbers only for the convenience of description and have no limiting effect.

The method for self-service terminal 100 may include:

S10: acquiring a first temperature measurement value of a first temperature sensor 61 located in a first cavity 10.

S20: comparing the first temperature measurement value with a first upper temperature threshold and/or a first lower temperature threshold.

A first control command for the temperature adjustment assembly 35 is generated to cause the temperature adjustment assembly 35 to conduct a cooling treatment for the first cavity 10, when the first temperature measurement value is higher than the first upper temperature threshold.

In some embodiments, when the first temperature measurement value is higher than the first upper temperature threshold, control commands for controlling the fans 31 and 32 are first generated to activate the fans, and after a delay of a predetermined period of time the first control command for the temperature adjustment assembly 35 is generated to cause the temperature adjustment assembly 35 to conduct a cooling treatment for the first cavity 10, and then the method jumps to step S30.

A second control command for the temperature adjustment assembly 35 is generated to cause the temperature adjustment assembly 35 to conduct a heating treatment for the first cavity 10, when the first temperature measurement value is lower than the first lower temperature threshold.

In some embodiments, when the first temperature measurement value is lower than the first lower temperature threshold, control commands for controlling the fans 31 and 32 are first generated to activate the fans, and after a delay of a predetermined period of time the second control command for the temperature adjustment assembly 35 is generated to cause the temperature adjustment assembly 35 to conduct a heating treatment for the first cavity 10, and then the method jumps to step S40.

S30: when the first temperature measurement value is lower than the cooling stop threshold, a deactivation command for the temperature adjustment assembly 35 is generated to cause the temperature adjustment assembly 35 to be deactivated, and after a delay of a predetermined period of time deactivation commands for controlling the fans 31 and 32 are generated to turn off the fans and then the method jumps to step S10.

S40: when the first temperature measurement value is higher than the heating stop threshold, a deactivation command for the temperature adjustment assembly 35 is generated to cause the temperature adjustment assembly 35 to be deactivated, and after a delay of a predetermined period of time deactivation commands for controlling the fans 31 and 32 are generated to turn off the fans and then the method jumps to step S10.

Additionally or alternatively, step S10 may further comprise: acquiring a second temperature measurement value of a second temperature sensor 62 located in a second cavity 20.

Step S20 may further include: comparing the second temperature measurement value with a lower operating temperature threshold for a power supply.

when the second temperature measurement value is lower than the lower operating temperature threshold for a power supply, a control command for the temperature regulating device 67 is generated to cause the temperature regulating device 67 to conduct a heating treatment for the power supply in the second cavity 20.

Step S40 may further include: when the second temperature measurement value is higher than the heating stop threshold for the power supply, a deactivation command for temperature regulating device 67 is generated to cause the temperature regulating device 67 to be deactivated, and then the method jumps to step S10.

Additionally or alternatively, in the case of a dual power supply configuration, the method for self-service terminal 100 may further include:

S60: in the startup stage of the self-service terminal 100, power is supplied by the primary power supply 65.

S70: acquiring the temperature in the cavity where the secondary power supply 66 is located (here, the second temperature measurement value of the second temperature sensor 62 located in the second cavity 20).

S80: comparing the temperature in the cavity where the secondary power supply 66 is located with the lower operating temperature threshold of the secondary power supply 66.

S90: when the temperature in the cavity where the secondary power supply 66 is located is higher than the lower operating temperature threshold, the secondary power supply 66 turns on;

S100: when the temperature in the cavity where the secondary power supply 66 is located is lower than the lower operating temperature threshold of the secondary power supply 66, a control command for the temperature regulating device 67 of the secondary power supply 66 is generated to cause the temperature regulating device 67 to conduct a heating treatment to the secondary power supply 66. When the temperature in the cavity where the secondary power supply 66 is located is higher than the heating stop threshold, a control command for the temperature regulating device 67 is generated to cause the temperature regulating device 67 to be deactivated, and then the method jumps to step S90.

Although exemplary embodiments of the present disclosure have been described, it will be understood by those skilled in the art that various changes and modifications can be made in the exemplary examples of the present disclosure without materially departing from the spirit and scope of the present disclosure. Accordingly, all changes and modifications are included within the scope of protection of the present disclosure as defined by the claims. The disclosure is defined by the appended claims, with equivalents of the claims to be included.

What is claimed is:

1. A self-service terminal, comprising:
a first cavity configured as a first accommodating space of the self-service terminal;
a second cavity configured as a second accommodating space of the self-service terminal;
a temperature adjustment assembly disposed between the first cavity and the second cavity, wherein the temperature adjustment assembly is configured to adjust the temperature within at least one of the first cavity and the second cavity, and wherein the temperature adjustment assembly is further configured to physically partition the first cavity and the second cavity.

2. The self-service terminal according to claim 1, wherein the temperature adjustment assembly is configured such that the first cavity and the second cavity are sealed from each other.

3. The self-service terminal according to claim 1, wherein the temperature adjustment assembly comprises:
a semiconductor temperature regulator, a first temperature regulating surface of the semiconductor temperature regulator faces the first cavity, and a second temperature regulating surface of the semiconductor temperature regulator faces the second cavity;
a first fan for the first temperature regulating surface; and
a second fan for the second temperature regulating surface.

4. The self-service terminal according to claim 3, further comprising a temperature control board within the second cavity, wherein the temperature control board is configured to control an operation of the temperature adjustment assembly.

5. The self-service terminal according to claim 4, further comprising a terminal control module communicatively connected to the temperature control board, wherein the terminal control module is provided in the first cavity, and wherein the terminal control module is configured to control an operation of a functional component within the first cavity.

6. The self-service terminal according to claim 4, wherein the temperature control board comprises:
a first output configured to be connected to a first control port of the semiconductor temperature regulator;
a first relay configured to selectively provide one of a first high voltage level or a first low voltage level to the first output and to the first control port of the semiconductor temperature regulator;
a second output configured to be connected to a second control port of the semiconductor temperature regulator;
a second relay configured to selectively provide one of a second high voltage level or a second low voltage level to the second output and to the second control port of the semiconductor temperature regulator;
a control unit configured to:
receive at least one of a first temperature measurement value of a first temperature sensor located in the first cavity and a second temperature measurement value of a second temperature sensor located in the second cavity; and
output a control command based on at least one of the first temperature measurement value and the second temperature measurement value;
a first drive circuit module configured to drive operating states of the first relay and the second relay based on the control command,
wherein one of the first high voltage level and the first low voltage level is provided to the first output via the first relay, and wherein one of the second high voltage level or the second low voltage level is provided to the second output via the second relay,
wherein when the first high voltage level is provided to the first output and the second low voltage level is provided to the second output, a first temperature regulating surface of the semiconductor temperature regulator is configured to function as a cooling surface and a second temperature regulating surface of the semiconductor temperature regulator is configured to function as a heating surface, and
when the first low voltage level is provided to the first output and the second high voltage level is provided to the second output, the first temperature regulating surface of the semiconductor temperature regulator is configured to function as the heating surface and the second temperature regulating surface of the semiconductor temperature regulator is configured to function as the cooling surface.

7. The self-service terminal according to claim 6, wherein the temperature control board comprises a second drive circuit module configured to drive the operation of at least one of the first fan and the second fan based on the control command, wherein activating at least one of the first fan and the second fan is performed earlier than activating the semiconductor temperature regulator by a predetermined period of time, and deactivating at least one of the first fan and the second fan is performed later than deactivating the semiconductor temperature regulator by a predetermined period of time.

8. The self-service terminal according to claim 6, further comprising a primary power supply, a secondary power supply and a temperature regulating device for the secondary power supply, wherein the primary power supply, the secondary power supply, and the temperature regulating device for the secondary power supply are provided in the second cavity,
wherein the primary power supply has a first upper operating temperature threshold and a first lower operating temperature threshold, and the secondary power supply has a second upper operating temperature threshold and a second lower operating temperature threshold, and
wherein the first upper operating temperature threshold is higher than the second upper operating temperature threshold, and the first lower operating temperature threshold is lower than the second lower operating temperature threshold.

9. The self-service terminal according to claim 8, wherein the temperature control board comprises a third drive circuit module configured to control operation of the temperature regulating device based on the control command,
wherein when the second temperature measurement value is lower than the second lower operating temperature threshold and higher than the first lower operating temperature threshold, the temperature regulating device is configured to function as a heater, and
wherein when the second temperature measurement value is higher than the second upper operating temperature threshold and lower than the first upper operating temperature threshold, the temperature regulating device acts is configured to function as a cooler.

10. The self-service terminal according to claim 6, further comprising an accommodating mechanism in the first cavity, and at least one of the terminal control module and a computer module are accommodated in the accommodating mechanism.

11. The self-service terminal according to claim 10, further comprising an air guide within the first cavity, wherein the air guide is configured to direct heated or cooled air flow from the first fan to at least one of the terminal control module and the computer module, and wherein the air guide is constructed as a covering of the accommodating mechanism.

12. The self-service terminal of claim 10, wherein the first cavity is bounded by metal plates laterally, and at least one of a thermal insulation layer and a reflective film is arranged on an inner surface of the metal plates.

13. The self-service terminal according to claim 10, wherein the second cavity is configured to be in a negative pressure state.

14. A self-service terminal, including:
a first cavity configured as an upper layer space of the self-service terminal, and a terminal control module is provided in the upper layer space;
a second cavity configured as a lower layer space of the self-service terminal, and a temperature control board is provided in the lower layer space; and
a temperature adjustment assembly arranged as an intermediate layer arranged between the first cavity and the second cavity, wherein the temperature control board is configured to control operation of the temperature adjustment assembly, wherein operation of the temperature assembly comprises maintaining a temperature in the first cavity within a predetermined temperature range.

15. The self-service terminal according to claim 14, wherein the temperature regulating component is configured to function as a cooler to lower the temperature in the first cavity when the temperature in the first cavity is higher than an upper temperature threshold and further configured to function as a heater to raise the temperature in the first cavity when the temperature in the first cavity is lower than a lower temperature threshold.

16. The self-service terminal according to claim 14, further comprising a power supply and a temperature regulating device for the power supply, wherein the power supply and the temperature regulating device are located in the lower layer space, and wherein the temperature control board is configured to control operation of the temperature regulating device to maintain temperature of the power supply within the predetermined temperature range.

17. A method for a self-service terminal, the method comprising:
acquiring a first temperature measurement value of a first temperature sensor located in a first cavity;
comparing the first temperature measurement value with a first upper temperature threshold and/or a first lower temperature threshold;
generating a first control command for a temperature adjustment assembly of the self-service terminal when the first temperature measurement value is higher than the first upper temperature threshold, wherein the first control command is configured to cause the temperature adjustment assembly to conduct a cooling treatment for a first cavity; and
generating a second control command for the temperature adjustment assembly when the first temperature measurement value is lower than the first lower temperature threshold, wherein the second control command is configured to cause the temperature adjustment assembly to conduct a heating treatment for the first cavity.

18. The method according to claim 17, further comprising:
acquiring a second temperature measurement value of a second temperature sensor located in a second cavity;
comparing the second temperature measurement value with at least one of a second upper temperature threshold and a second lower temperature threshold;
generating a third control command for the temperature regulating device when the second temperature measurement value is higher than the second upper temperature threshold, wherein the third control command is configured to cause the temperature regulating device to conduct a cooling treatment on a power supply in the second cavity; and
generating a fourth control command for the temperature regulating device when the second temperature measurement value is lower than the second lower temperature threshold, wherein the fourth control command is configured to cause the temperature regulating device to conduct a heating treatment on the power supply in the second cavity.

19. The method according to claim 17, further comprising:
generating a fifth control command for a fan located in the second cavity to cause the second cavity being in a negative pressure state.

20. The method according to claim 17, further comprising:
comparing the second temperature measurement value to an upper operating temperature threshold and/or a lower operating temperature threshold of a power supply;
activating the power supply to supply power when the second temperature measurement value is lower than the upper operating temperature threshold of the power supply and higher than the lower operating temperature threshold of the power supply;
generating a cooling command for the temperature regulating device when the second temperature measurement is higher than the upper operating temperature threshold of the power supply, wherein the cooling command is configured to cause the temperature regulating device to conduct a cooling treatment for the power supply; and
generating a heating command for the temperature regulating device when the second temperature measurement value is lower than the lower operating temperature threshold of the power supply, wherein the heating command is configured to cause the temperature regulating device to conduct a heating treatment for the power supply.
